(19) United States
(12) Patent Application Publication
(10) Pub. No.: US 2015/0040965 A1
(43) Pub. Date: Feb. 12, 2015

(54) Ground Mount Structure With Mounting Assemblies And Central Quick-Mount Rail

(71) Applicant: Zep Solar LLC, San Rafael, CA (US)

(72) Inventors: Jack Raymond West, San Rafael, CA (US); Brian Atchley, San Rafael, CA (US); Tyrus Hawkes Hudson, San Rafael, CA (US)

(21) Appl. No.: 14/453,329

(22) Filed: Aug. 6, 2014

Related U.S. Application Data
(60) Provisional application No. 61/864,638, filed on Aug. 12, 2013.

(51) Int. Cl. H01L 31/042

(52) U.S. Cl. CPC H01L 31/0422; H02S 20/00
USPC 136/246

(57) ABSTRACT

A solar array having three rails with the central rail having upward and downward facing pivot connectors, with top and bottom photovoltaic modules being pivot mounted onto the shared central rail such that the two photovoltaic modules are supported by three mounting rails.

### RELATED APPLICATION

The present application claims priority to U.S. Provisional Patent Application 61/864,638, of same title, filed Aug. 12, 2013.

### TECHNICAL FIELD

The present invention relates to solar arrays, preferably including, but not limited to, ground mounted solar arrays.

### BACKGROUND OF THE INVENTION

Existing ground mounted solar arrays are structures which position and support photovoltaic modules at a preferred angle to the ground. Typically, these mounting structures are designed with each row of modules being fastened onto a pair of rails passing beneath. Normally, the module is fastened to one rail close to the top end of the module, and is fastened to the other rail close to the bottom end of the module.

Such systems require considerable time to assemble since connections must be made to two separate rails for each row of modules. What is instead desired is a system that enables fast and easy set-up of a photovoltaic module array, while also minimizing the number of parts used. Ideally, such a system would not require the installers to manually lift the photovoltaic modules to heights far over their heads during assembly of the array.

### SUMMARY OF THE INVENTION

In accordance with the present invention, a shared rail mounting system is provided with two rows of photovoltaic modules mounted onto three mounting rails.

In preferred aspects, the present invention provides a solar array, comprising: (a) a mounting structure; (b) an upper horizontal rail extending along the mounting structure; (b) a lower horizontal rail extending along the mounting structure; (c) a central horizontal rail extending along the mounting structure, the central horizontal rail being positioned between the upper and lower horizontal rails; (d) an upward facing pivot connector on the central horizontal rail; (e) a top photovoltaic module having a lower end pivot mounted onto the upward facing pivot connector; (f) a downward facing pivot connector on the central horizontal rail; and (g) a bottom photovoltaic module having an upper end pivot mounted onto the downward facing pivot connector.

Preferably, the top and bottom photovoltaic modules have grooved frames that are pivot locked onto the upward and downward facing pivot connectors on the shared central horizontal rail. Optionally, the grooves in these grooved frames may be angled to the top surfaces of the photovoltaic modules, with the male connectors being dimensioned to slide into the grooves at an angle and then push against the top and bottom of the grooves when pivoted into a locked position.

A first advantage of the present system is that it supports two rows of photovoltaic modules using only three horizontal rails. This is achieved by sharing the middle horizontal rail between the upper and a lower photovoltaic modules.

A second advantage of the present system is that it provides a fast, easy pivot locking system. This is achieved by a pivot locking connection being made between each of the upper and lower ends of the photovoltaic modules and the pivot connectors on the central horizontal mounting rail. As will be explained, it is quick and easy for an operator to pivot lock each of the rows of modules into position.

A third advantage of the present system is that an installer is able to install both rows of modules without the operator having to lift either of the modules to heights far over their heads.

### BRIEF DESCRIPTION OF THE DRAWINGS

FIGS. 1A to 1I are sequential, schematic steps illustrating the installation of two rows of photovoltaic modules on a ground mounted structure, as follows:

FIG. 1A to 1C shows an installer sequentially lifting an upper photovoltaic module into position, and dropping it into position over the top of the mounting structure. Next, FIG. 1D shows the installer pivot locking the upper photovoltaic module into position. Finally, FIG. 1E shows the upper photovoltaic module in its final position.

FIGS. 1F and 1G show the installer first lifting the lower photovoltaic module into position. Next,

FIG. 1H shows the installer pivot locking the lower photovoltaic module into position. Finally,

FIG. 1I shows the lower photovoltaic module in its final position.

FIG. 2 is a side elevation view of the present system (with the photovoltaic modules shown in solid lines in their final locked position and dotted lines prior to being pivoted into their final locked positions).

FIG. 3 is a perspective view of the present system.

FIG. 4 is a close-up view of the pivot connectors on the shared central rail.

### DETAILED DESCRIPTION OF THE DRAWINGS

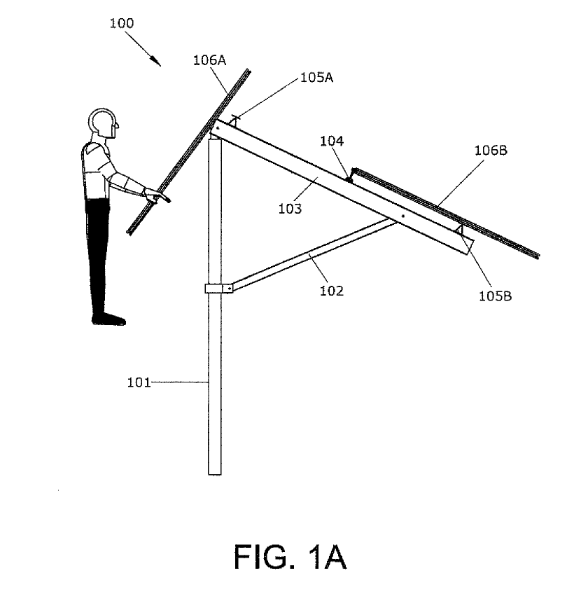

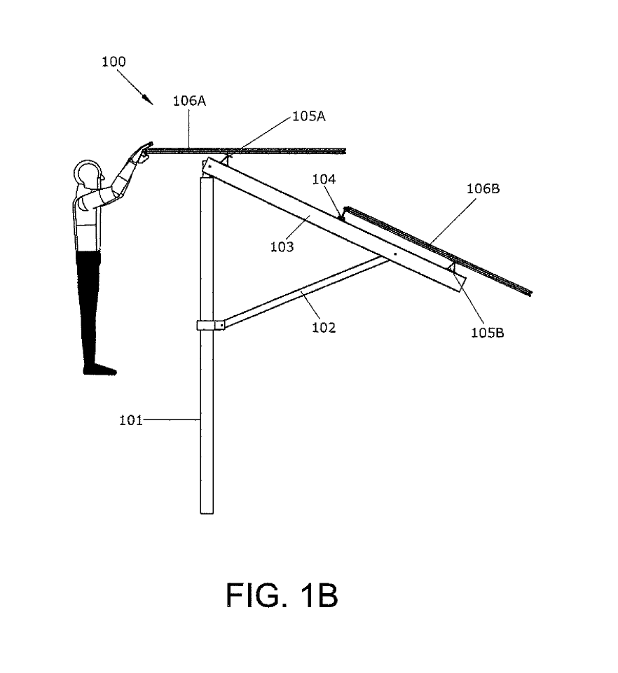

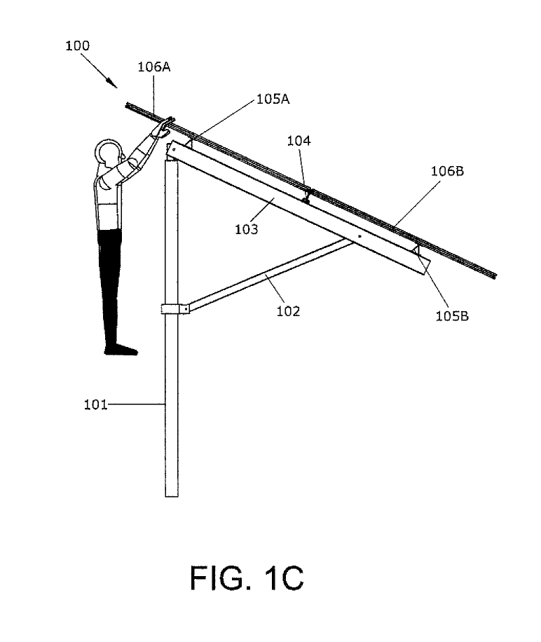

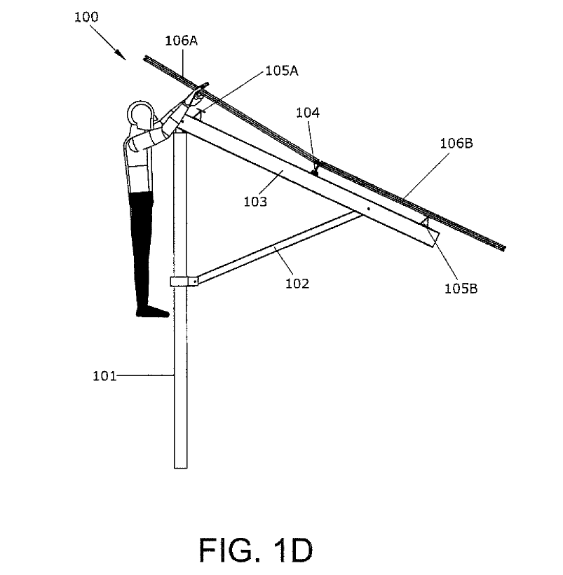

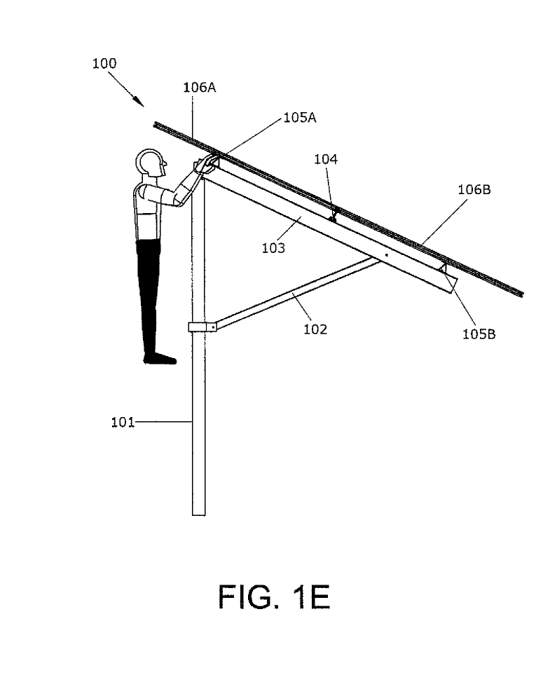

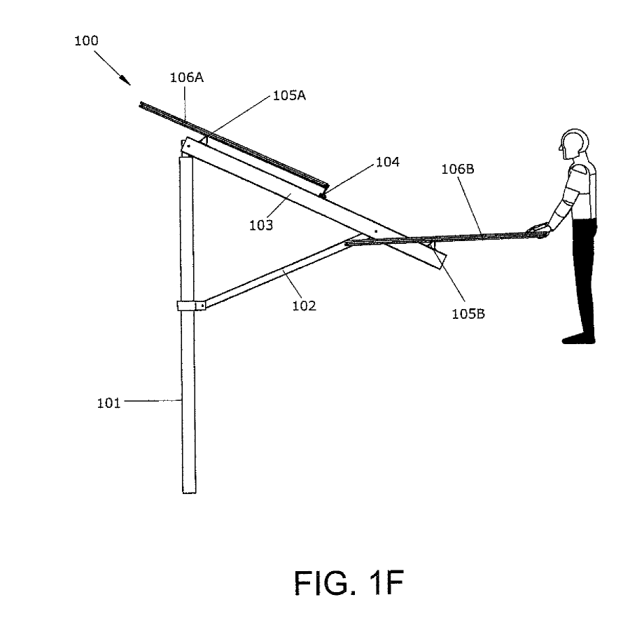

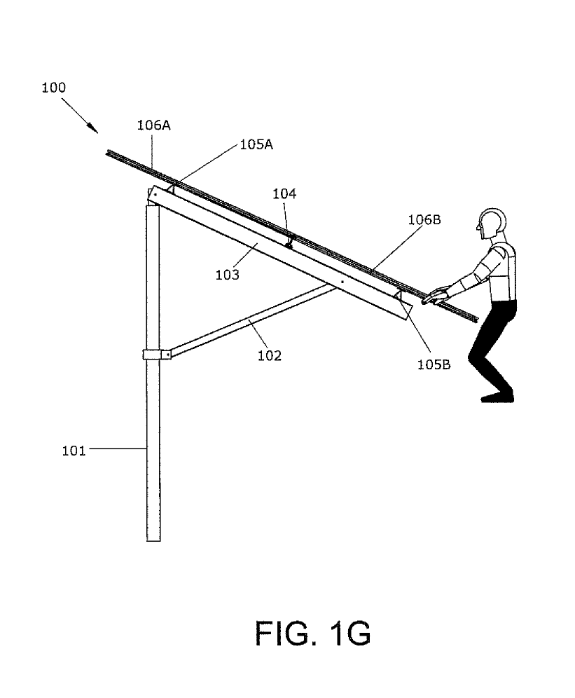

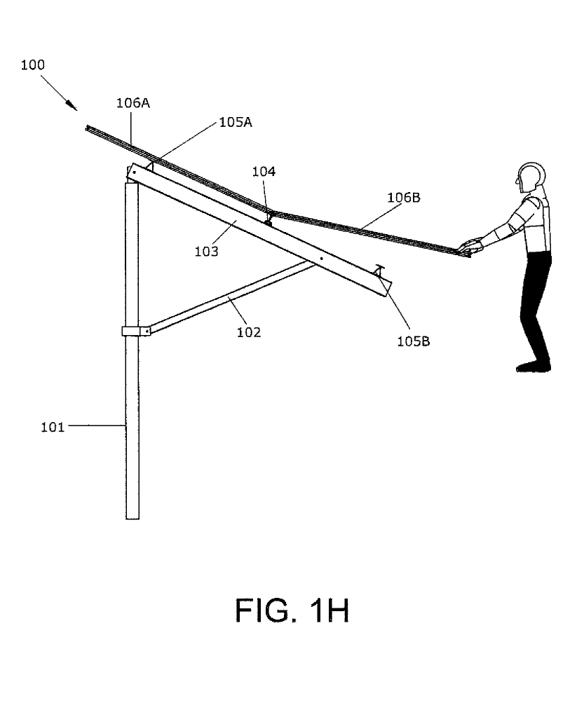

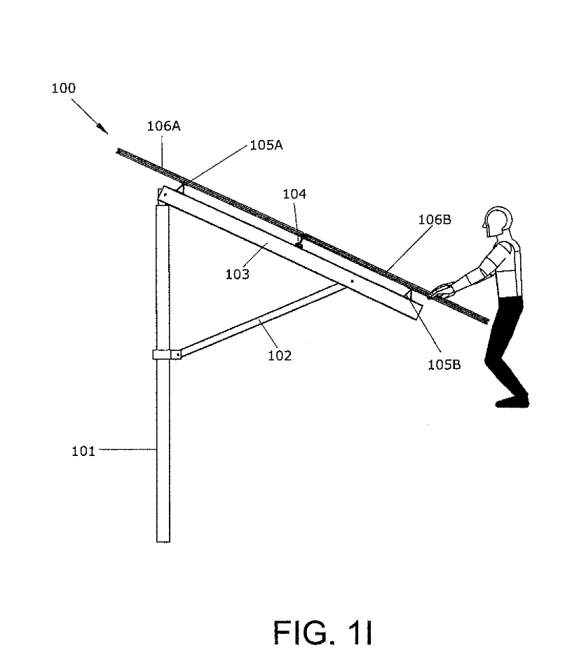

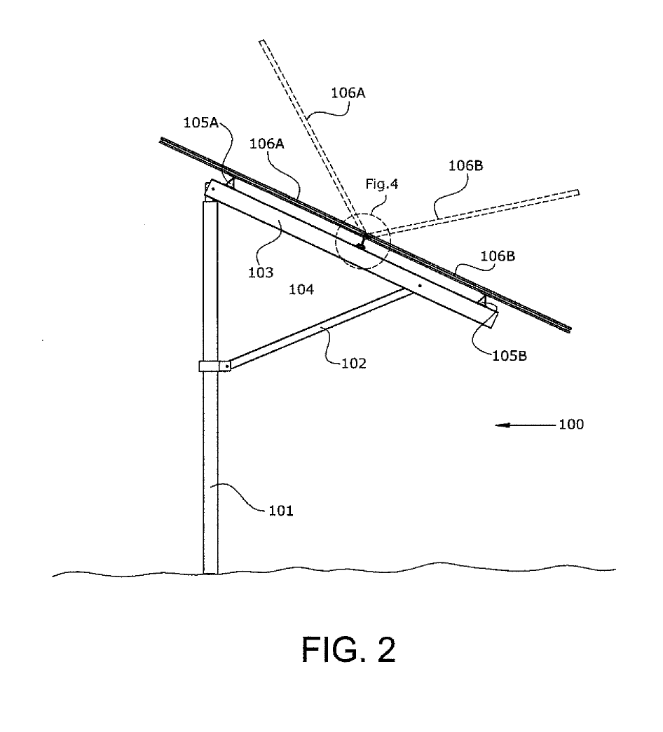

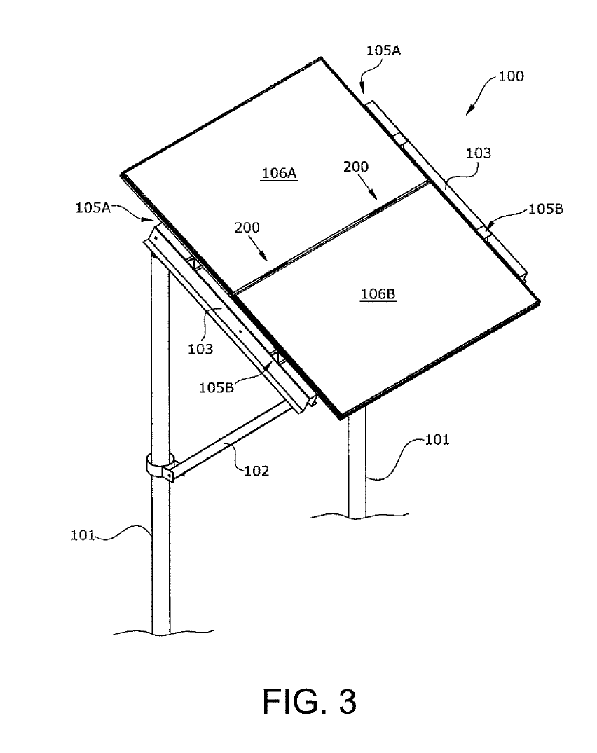

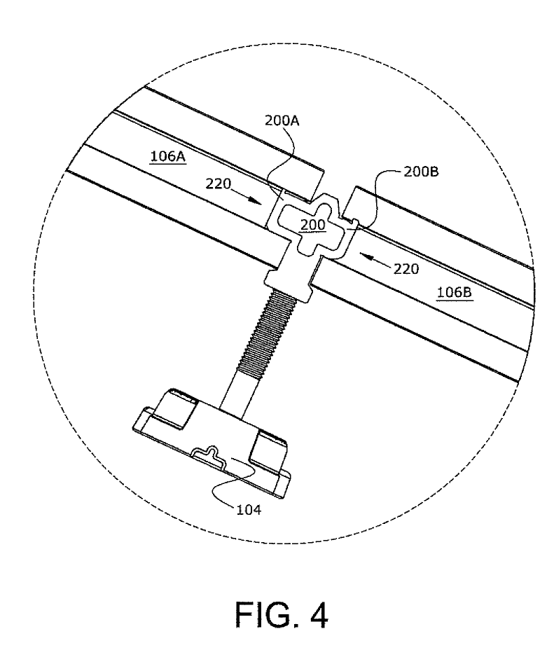

FIGS. 1A to 1L show sequential steps of the installation of an upper and lower photovoltaic module using a shared central rail system. FIGS. 2 and 3 show overall views of this system. FIG. 4 is a close-up view of the pivot connectors.

Referring first to the attached FIGS. 1, 2 and 3, a ground mounting system 100 is provided. Ground mounting system 100 includes a pair of vertical posts 101; a pair of diagonal posts 103 extending downwardly at an angle from each of vertical posts 101; and a pair of brace posts 102 extending between each vertical post 101 and each diagonal post 103. As can be seen, an upper rail 105A extends between the pairs of vertical posts 101. A lower rail 105B extends between the pairs of diagonal posts 103. A central horizontal rail 104 also extends between the pairs of diagonal posts 103.

FIG. 4 is a close-up view of the pivot-connectors 200 mounted on the shared central rail 104. Pivot-connectors 200 comprise an upward facing pivot connector 200A and a downward facing pivot connector 200B.

During installation, a top row of modules and a bottom row of modules are installed. These two module rows can be installed in either order. However, it is more common to install the upper row of photovoltaic modules first.

FIGS. 1A to 1C show installation of upper module 106A. First, in FIG. 1A, the installer lifts module 106A onto the back of the mounting structure, and then (as seen in FIG. 1B), rotates the module 106A over the top of upper mounting rail 105A. Finally, the module 106A is rotated downwardly to the position seen in FIG. 1C. The advantage of this approach is that the installer need not lift module 106A too far over their head. Rather, it is simply rotated over upper rail 105A.

Next, as seen in FIG. 1D, the installer places upper photovoltaic module 106A in a position such that its groove 220 (as seen in FIG. 4) in its lower end can be inserted onto upward facing pivot connector 200A (as seen in FIG. 4). Next, as seen in FIG. 1E, upper photovoltaic module 106A is pivoted downwardly such that it locks into position. Examples of the pivot coupling structure can be seen in Applicant's Published Patent Application 2012/0298817, entitled Pivot-Fit Frame, System and Method For Photovoltaic Arrays, incorporated herein by reference. It is to be understood, however, that the present invention is not limited to any particular form of pivot connector. Thus, the embodiment shown in FIG. 4 is exemplary, and not limiting. For example, pivot connections may include wrap-around embodiments to connect to modules that do not have grooved frames.

After the bottom end of photovoltaic module 106A has been pivoted into position, the upper end of upper photovoltaic module 106A can be connected onto upper horizontal bar 105A using any suitable technique, including attachment and mounting systems common in the field. After upper module 106A has been locked into position, lower module 106B can be attached, as follows.

First, as seen in FIG. 1F, the installer first raises the lower photovoltaic module 106B, and may simply place photovoltaic module 106B overtop of lower horizontal bar 105B. (Note: in this view, lower module 106B is positioned between the pair of vertical supports 103; therefore, a section of one vertical support 103 has been cut away). Next, as seen in FIG. 1G, the installer may push down on the free end of photovoltaic module 106B, causing its top end to line up with central rail 104. Next, the installer may lift the free end of photovoltaic module 106B as seen in FIG. 1H, such that its groove 220 (as seen in FIG. 4) in its upper end can be inserted onto downward facing pivot connector 200B (as seen in FIG. 4). Next, as seen in FIG. 1I, lower photovoltaic module 106B is pivoted downwardly such that it locks into position. After the top end of photovoltaic module 106B has been pivoted into position, the lower end of lower photovoltaic module 106B can be connected onto lower horizontal bar 105B using any suitable technique, including attachment and mounting systems common in the field.

In various optional preferred embodiments, the grooves 220 in the grooved photovoltaic module frames may be angled to the top surfaces of the photovoltaic modules. Examples of this design are also seen in Published Patent Application 2012/0298817, entitled Pivot-Fit Frame, System and Method For Photovoltaic Arrays, incorporated herein by reference. In this exemplary design, as seen in FIG. 4, male connectors (200A and 200B) are dimensioned to slide into the grooves 220 at an angle and then push against the top and bottom of the groove when pivoted into a final locked position. In alternate designs, upward facing pivot connector 200A and downward facing pivot connector 200B may be separate devices mounted onto central rail 104, or they may be opposite ends of the same device (as illustrated in FIG. 4). It is to be understood, however, that the present invention is not limited to any particular form of pivot connector. Thus, the embodiment shown in FIG. 4 is exemplary, and not limiting. For example, pivot connections may include wrap-around embodiments to connect to modules that do not have grooved frames.

What is claimed is:

1. A solar array, comprising:
(a) a mounting structure;
(b) an upper horizontal rail extending along the mounting structure;
(b) a lower horizontal rail extending along the mounting structure;
(c) a central horizontal rail extending along the mounting structure, the central horizontal rail being positioned between the upper and lower horizontal rails;
(d) an upward facing pivot connector on the central horizontal rail;
(e) a top photovoltaic module having a lower end pivot mounted onto the upward facing pivot connector;
(f) a downward facing pivot connector on the central horizontal rail; and
(g) a bottom photovoltaic module having an upper end pivot mounted onto the downward facing pivot connector.

2. The solar assembly of claim 1, wherein the top and bottom photovoltaic modules have grooved frames that are pivot locked onto the upward and downward facing pivot connectors on the central horizontal rail.

3. The solar assembly of claim 2, wherein the upward and downward facing pivot connectors are male connectors that are received into grooves in the grooved frames.

4. The solar assembly of claim 1, wherein the mounting structure comprises:
(a) a pair of vertical posts;
(b) a pair of diagonal posts, each diagonal post extending downwardly at an angle from one of the of the vertical posts; and
(c) a pair of brace posts, each brace post extending between one of the vertical posts and one of the diagonal posts.

5. The solar assembly of claim 4, wherein each of the upper, lower and central horizontal rails extend between the pair of vertical posts.
